(19) United States
(12) Patent Application Publication
(10) Pub. No.: US 2022/0320000 A1
(43) Pub. Date: Oct. 6, 2022

(54) Integrated Assemblies and Methods of Forming Integrated Assemblies

(71) Applicant: Micron Technology, Inc., Boise, ID (US)

(72) Inventor: Yuichi Yokoyama, Boise, ID (US)

(73) Assignee: Micron Technology, Inc., Boise, ID (US)

(21) Appl. No.: 17/222,331

(22) Filed: Apr. 5, 2021

(51) Int. Cl. H01L 23/532; H01L 27/108; G11C 5/06; H01L 23/528

(52) U.S. Cl. CPC H01L 23/53257; H01L 27/10897; H01L 27/10885; H01L 27/10888; G11C 5/063; H01L 23/5283

(57) ABSTRACT

Some embodiments include an integrated assembly having a first connection region with first contact pads. A second connection region is offset from the first connection region along a first direction. Second contact pads are within the second connection region. A memory array region is between the first and second connection regions. First conductive lines extend from the first contact pads of the first connection region and across the memory array region. Second conductive lines extend from the second contact pads of the second connection region and across the memory array region. The first conductive lines, second conductive lines, first contact pads and second contact pads have an identical conductive composition as one another. Some embodiments include methods of forming integrated assemblies.

### TECHNICAL FIELD

Integrated assemblies (e.g., integrated memory). Methods of forming integrated assemblies.

### BACKGROUND

Memory is one type of integrated circuitry, and is used in computer systems for storing data. Memory may be fabricated in one or more arrays of individual memory cells. Memory cells may be written to, or read from, using digit lines (which may also be referred to as bitlines, data lines, sense lines, or data/sense lines) and access lines (which may also be referred to as wordlines). The digit lines may extend along columns of the array, and the access lines may extend along rows of the array. Each memory cell may be uniquely addressed through the combination of a digit line and an access line.

Memory cells may be volatile or nonvolatile. Nonvolatile memory cells can store data for extended periods of time, including when a computer is turned off. Volatile memory dissipates and therefore is rapidly refreshed/rewritten, in many instances multiple times per second. Regardless, memory cells are configured to retain or store memory in at least two different selectable states. In a binary system, the states are considered as either a “0” or a “1”. In other systems, at least some individual memory cells may be configured to store more than two levels or states of information.

One type of memory is dynamic random-access memory (DRAM). The individual DRAM cells may include a transistor in combination with a capacitor (or other suitable charge-storage device). The transistor is utilized to selectively access the capacitor, and may be referred to as an access device. The capacitor may electrostatically store energy as an electric field within capacitor dielectric between two capacitor electrodes. The electrical state of the capacitor may be utilized to represent a memory state.

The wordlines may be coupled with wordline-driver-circuitry, and the digit lines may be coupled with sense-amplifier-circuitry. The wordline-driver-circuitry and sense-amplifier-circuitry may be within a CMOS region of an integrated assembly.

Memory is one example of integrated circuitry, and many other types of integrated circuitry are known (e.g., sensor circuitry, logic circuitry, etc.). Such other types of integrated circuitry may be utilized in combination with integrated memory in some applications.

A continuing goal of integrated assembly fabrication is to increase the level of integration, or, in other words, to pack ever-more memory into ever-decreasing space. It is desired to develop new architectures for integrated assemblies, and it is desired for such new architectures to be suitable for highly-integrated applications.

### BRIEF DESCRIPTION OF THE DRAWINGS

FIG. 1 is a diagrammatic top-down view of an example region of an example integrated assembly at an example process stage of an example method. FIG. 1A is a diagrammatic cross-sectional side view along the line A-A of FIG. 1.

FIGS. 2-7 are diagrammatic top-down views of the example region of FIG. 1 at example sequential process stages subsequent to that of FIG. 1. FIGS. 7A and 7B are diagrammatic cross-sectional side views along the lines A-A and B-B of FIG. 7, respectively.

FIG. 8 is diagrammatic top-down view of the example region of FIG. 1 at an example process stage subsequent to that of FIG. 7. FIG. 8A is a diagrammatic cross-sectional side view along the line A-A of FIG. 8.

FIG. 9 is a diagrammatic top-down view of example regions of an example integrated assembly, with some of such regions being formed utilizing the processing of FIGS. 1-8.

FIGS. 10 and 11 are diagrammatic top-down views of an example region of an example integrated assembly at example process stages of an example method.

FIGS. 11A-11E are diagrammatic top-down views of an example region of an example integrated assembly showing example process stages for fabricating example spacers that may be utilized in FIG. 11.

FIGS. 12-16 are diagrammatic top-down views of the example region of FIG. 10 at example sequential process stages subsequent to that of FIG. 11.

FIG. 17 is a diagrammatic top-down view of example regions of an example integrated assembly, with some of such regions being formed utilizing the processing of FIGS. 10-16.

### DETAILED DESCRIPTION OF THE ILLUSTRATED EMBODIMENTS

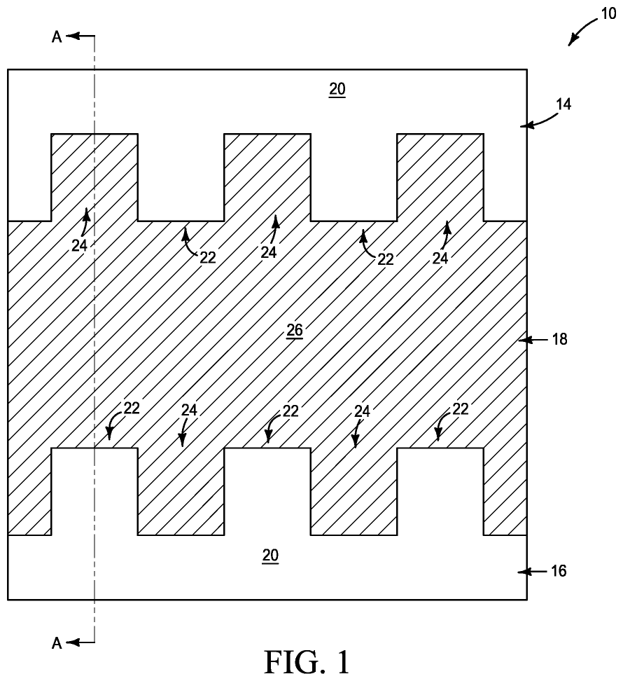

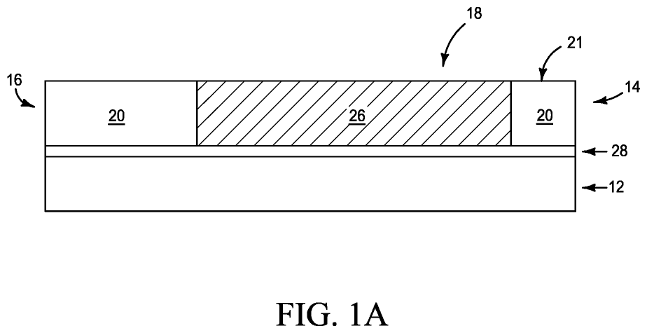

Some embodiments include methods which may be utilized to pattern metal (e.g., ruthenium) into conductive lines and contact pads (landing pads). The conductive lines may be configured as digit lines and/or wordlines of a memory array. For instance, the conductive lines may be configured as digit lines, and the contact pads may be utilized for electrically coupling the digit lines with sense-amplifier-circuitry. Some embodiments include integrated assemblies having conductive structures corresponding to conductive lines and contact pads, with such conductive structures comprising a same composition (e.g., comprising ruthenium) throughout the conductive lines and the contact pads. Example embodiments are described with reference to FIGS. 1-17.

Referring to FIG. 1, a portion of an integrated assembly 10 is illustrated. The assembly includes insulative structures 14 and 16, and includes a metal-containing mass 18 which is formed to be adjacent to the insulative structures 14 and 16.

The insulative structures 14 and 16 comprise insulative material 20. The insulative material 20 may comprise any suitable composition(s); and may, for example, comprise, consist essentially of, or consist of one or more of silicon dioxide, silicon nitride, aluminum oxide, hafnium oxide, zirconium oxide, etc.

The metal-containing mass 18 comprises conductive metal-containing material 26. The material 26 may comprise, for example, one or more of various metals (e.g., titanium, tungsten, cobalt, nickel, platinum, ruthenium, etc.) and/or one or more of various metal-containing compositions (e.g., metal silicide, metal nitride, metal carbide, etc.). In some applications, the material 26 of the metal-containing mass 18 may comprise, consist essentially of, or consist of ruthenium. Ruthenium has excellent conductivity, even when formed into very thin structures. Accordingly, ruthenium may be a desirable conductive material for highly-integrated circuitry. However, it can be difficult to pattern ruthenium into desired configurations. In some embodiments, methods are disclosed which may be suitable for patterning ruthenium into highly-integrated assemblies.

The illustrated insulative structures 14 and 16 are configured as comb-type patterns having projecting teeth 22, and having recesses 24 laterally between the teeth. Alternatively considered, the illustrated insulative structures 14 and 16 may be considered to be configured to include projections 22, and to include bay regions 24 laterally between the projections.

The metal-containing mass 18 extends into the recesses (bay regions) 24.

FIG. 1A shows a cross-sectional side view along the line A-A of FIG. 1. In the shown application, the structures 14, 16 and 18 are supported by a base 12. The base 12 may comprise semiconductor material; and may, for example, comprise, consist essentially of, or consist of monocrystalline silicon. The base 12 may be referred to as a semiconductor substrate. The term “semiconductor substrate” means any construction comprising semiconductive material, including, but not limited to, bulk semiconductive materials such as a semiconductive wafer (either alone or in assemblies comprising other materials), and semiconductive material layers (either alone or in assemblies comprising other materials). The term “substrate” refers to any supporting structure, including, but not limited to, the semiconductor substrates described above. In some applications, the base 12 may correspond to a semiconductor substrate containing one or more materials associated with integrated circuit fabrication. Such materials may include, for example, one or more of refractory metal materials, barrier materials, diffusion materials, insulator materials, etc.

An insulative layer 28 is formed over the base, and the structures 14, 16 and 18 are formed over the insulative layer 28. The insulative layer 28 may comprise any suitable composition(s), such as, for example, one or more of silicon dioxide, silicon nitride, aluminum oxide, etc. The insulative layer 28 may or may not comprise a same composition as the structures 14 and 16. The insulative layer 28 provides electrical isolation between the metal-containing mass 18 and the base 12. In some embodiments, the regions of the layer 28 under the insulative structures 14 and 16 may be omitted, and the insulative structures 14 and 16 may be instead formed directly against an upper surface of the base 12.

In the shown embodiment, a planarized surface 21 extends across the materials 20 and 26 of the structures 14, 16 and 18. The planarized surface 21 may be formed with any suitable processing, including, for example, chemical-mechanical polishing (CMP).

The configuration of FIGS. 1 and 1A may be formed with any suitable methodologies, either now known or yet to be developed. In some embodiments, the metal-containing mass 18 may be formed within an opening between the insulative structures 14 and 16 utilizing damascene processing.

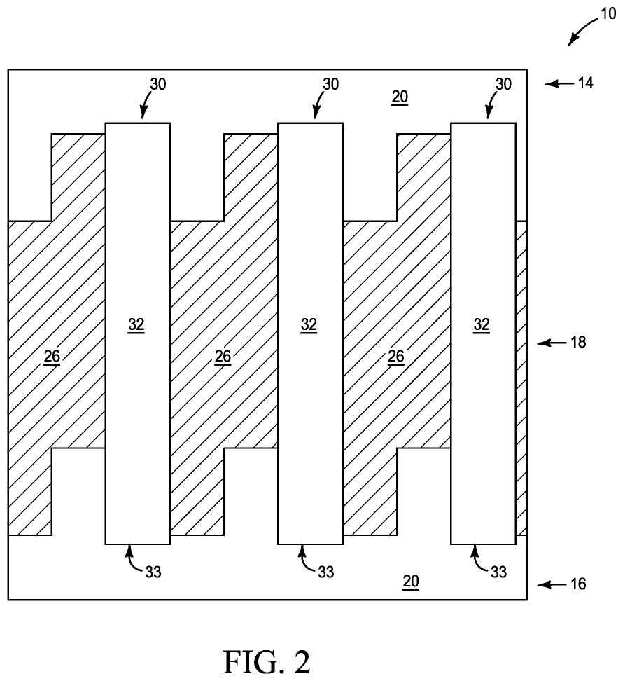

Referring to FIG. 2, template structures 30 are formed over the metal-containing material 26 of the mass 18. The template structures are configured as rectangular blocks in the illustrated embodiment. In other embodiments, the template structures may have other configurations.

The template structures comprise a patterned material 32. The material 32 may comprise any suitable composition(s), and in some embodiments may comprise photolithographically-patterned photoresist. The template structures may be homogenous (as shown) or may comprise laminates of two or more different compositions.

The template structures 30 have outer edges 33, with such outer edges extending around lateral peripheries of the template structures.

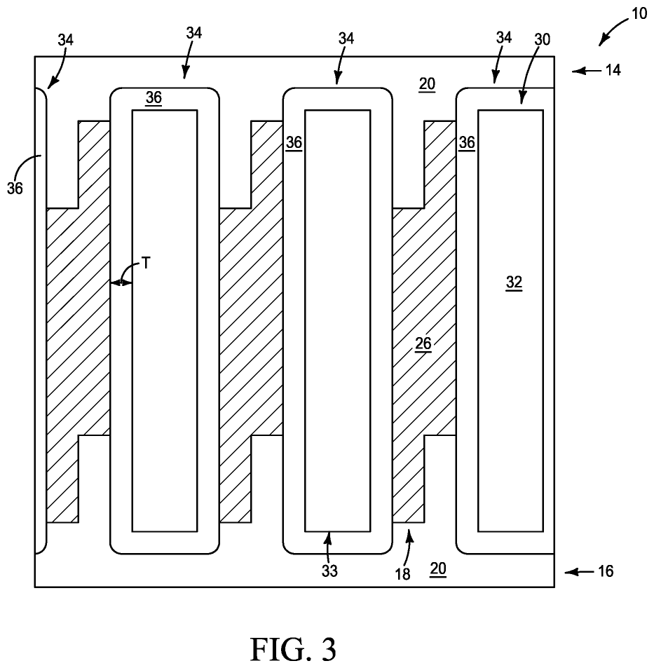

Referring to FIG. 3, spacers 34 are formed along the outer edges 33. The spacers 34 comprise spacer material 36. The spacer material may comprise any suitable composition(s). In some embodiments, the spacer material may comprise, consist essentially of, or consist of one or more of silicon dioxide, silicon nitride, aluminum oxide, hafnium oxide, zirconium oxide, etc.

The spacers 34 may be formed with any suitable processing. For instance, in some embodiments the spacer material 36 may be formed selectively along surfaces of the template structures 30 utilizing atomic layer deposition (ALD). In some embodiments, the spacers 34 may be formed by initially forming the spacer material 36 to extend across the entire upper surface of the assembly 10, and subsequently anisotropically etching the spacer material to form the spacers 34.

The spacers 34 may have any suitable thickness T along the outer edges 33 of the template structures 30. In some embodiments, such thickness may be within a range of from about 3 nanometers (nm) to about 15 nm.

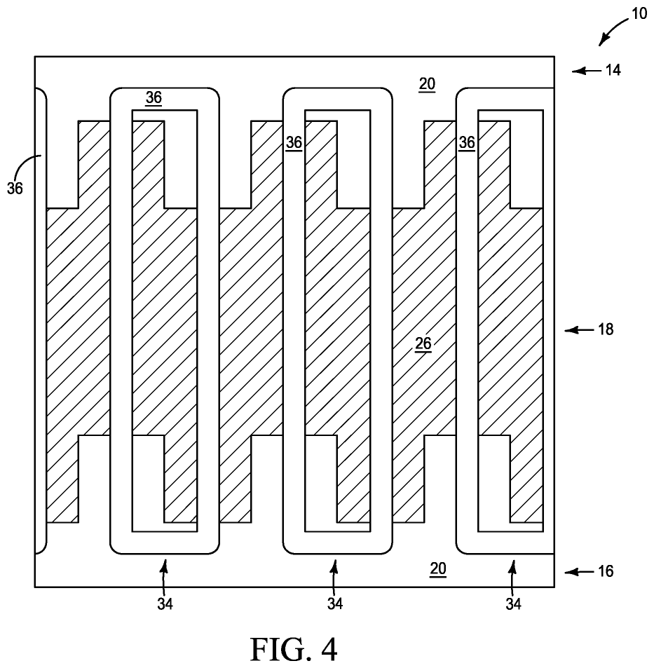

Referring to FIG. 4, the template structures 30 (FIG. 3) are removed. The spacers 34 remain as rings, with regions of such rings extending across the metal-containing material 26 of the mass 18.

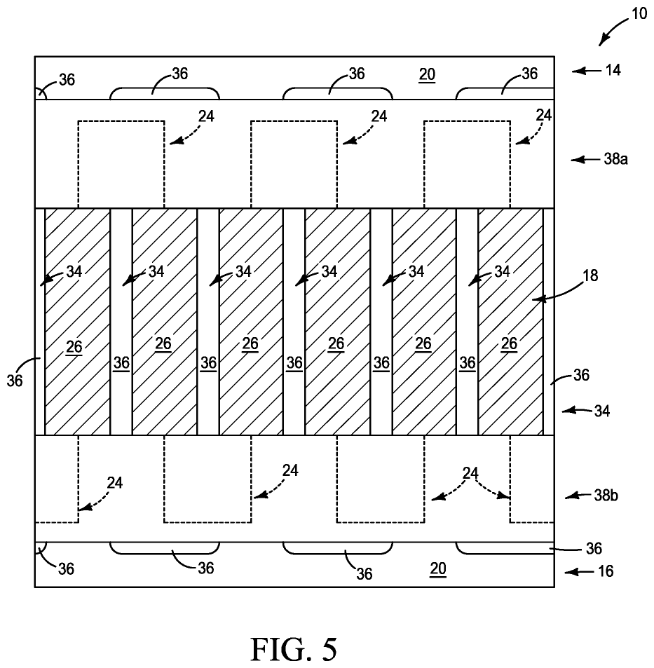

Referring to FIG. 5, masking structures 38a and 38b are formed over regions of the metal-containing mass 18. In the illustrated embodiment, the masking structures 38a and 38b extend across the bay regions 24 described above with reference to FIG. 1. Such bay regions are diagrammatically indicated with dashed lines to assist the reader in understanding the orientation of the masking structures 38a and 38b relative to the bay regions 24. The masking structures 38a and 38b may be utilized to protect the metal-containing material 26 within the bay regions 24 during a subsequent etch, with the protected metal-containing material being thereby patterned into contact pads. Accordingly, in some embodiments the masking structures 38a and 38b may be referred to as contact-pad-defining masking structures. In the illustrated embodiment, each of the contact-pad-defining masking structures 38a and 38b extends across several of the bay regions 24. Generally, each of the illustrated contact-pad-defining masking structures 38a and 38b of FIG. 5 may be considered to be representative of a masking structure that extends across two or more of the bay regions 24.

Although two of the contact-pad-defining masking structures 38a and 38b are shown in the illustrated embodiment of FIG. 5, it is to be understood that in other embodiments there may be a different number of the contact-pad-defining masking structures formed at such process stage. Generally, there may be one or more of the contact-pad-defining masking structures 38 formed at the process stage of FIG. 5.

The masking structures 38a and 38b may comprise any suitable composition(s), and in some embodiments may comprise, consist essentially of, or consist of photolithographically-patterned photoresist.

In the illustrated embodiment of FIG. 5, the masking structures 38a and 38b are formed over the spacer material 36 of the spacers 34, and accordingly are formed over regions of the spacers 34. In other embodiments, the masking structures 38a and 38b may be formed prior to the spacers 34 so that the regions of the spacers 34 are over the masking structures 38a and 38b rather than being under such masking structures.

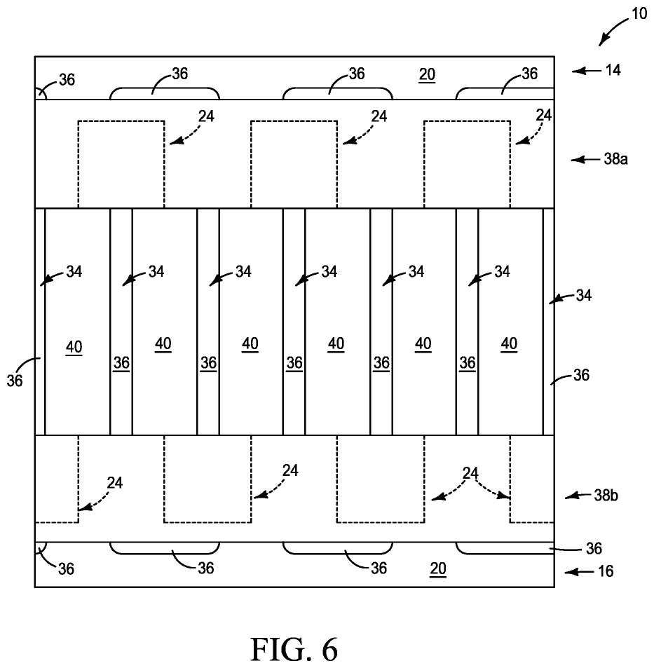

Referring to FIG. 6, exposed portions of the metal-containing material 26 (shown in FIG. 5) are removed, and insulative material 40 is provided to replace the removed metal-containing material 26. The insulative material 40 may comprise any suitable composition(s); and may, for example, comprise one or more of silicon nitride, silicon dioxide, aluminum oxide, etc.

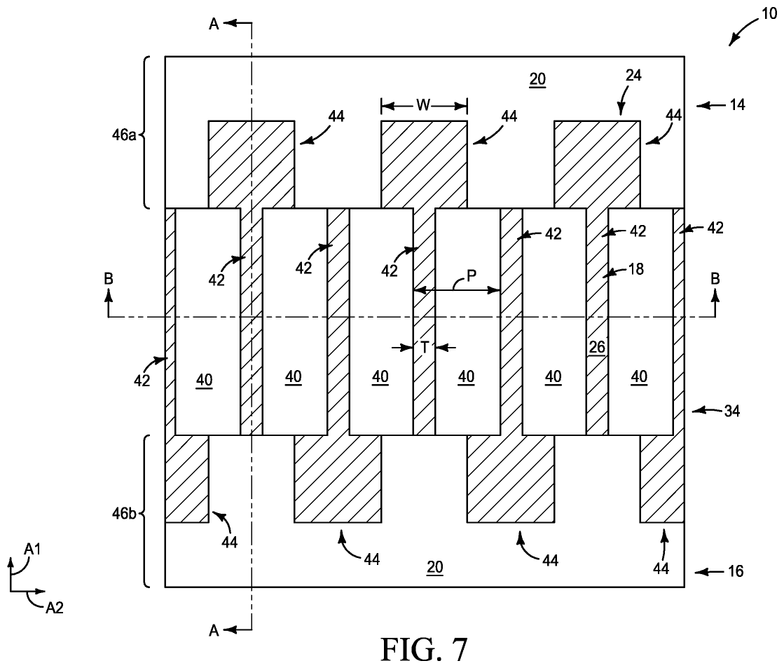

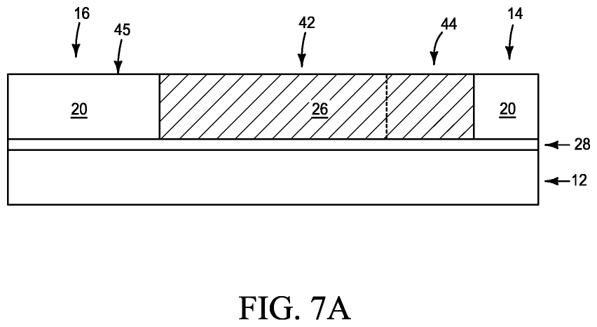

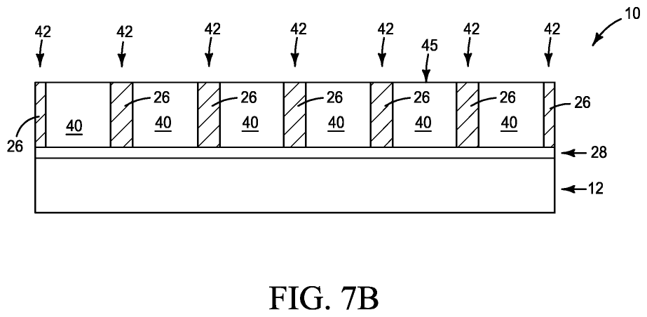

Referring to FIG. 7, the spacers 34 (FIG. 6) and masking structures 38a/38b (FIG. 6) are removed. The remaining metal-containing material 26 of the metal-containing mass 18 is patterned into conductive lines 42 and contact pads 44. The contact pads 44 are within the bay regions 24. In some embodiments, the removal of the exposed metal-containing material described above with reference to FIG. 5 may be considered to be a transfer of the pattern of the spacers 34 (FIG. 5) and the contact-pad-defining masking structures 38a/38b (FIG. 5) into the metal-containing mass 18 to thereby pattern the conductive lines 42 and contact pads 44 of FIG. 7.

The conductive lines 42 have about the thickness T of the spacers 34. The thickness T may be within a range of from about 3 nm to about 15 nm.

The contact pads (landing pads) 44 have widths W. Such widths may be, for example, within a range of from about 15 nm to about 50 nm.

The conductive lines 42 are formed to be on a pitch P. Such pitch may be, for example, within a range of from about 20 nm to about 50 nm. Accordingly, the thin conductive lines 42 may be incorporated into highly-integrated architectures.

The conductive lines 42 and contact pads 44 are patterned from the same conductive material 26, and accordingly comprise a same composition as one another. In some embodiments, such composition may comprise, consist essentially of, or consist of ruthenium.

The contact pads 44 may be considered to be within connection regions 46a and 46b, and the conductive lines 42 may be considered to extend from such connection regions. In the illustrated embodiment, the conductive lines extend along a first direction indicated as an A1-axis direction. The contact pads 44 within the first connection region 46a are aligned with one another along a second direction indicated as an A2-axis direction, and the contact pads 44 within the second connection region 46b are also aligned with one another along the A2-axis direction. In the shown embodiment, the A1-axis direction is substantially orthogonal to the A2-axis direction, with the term “substantially orthogonal” meaning orthogonal to within reasonable tolerances of fabrication and measurement.

FIGS. 7A and 7B show cross-sections along the lines A-A and B-B, respectively, of FIG. 7. In the illustrated embodiment, a planarized surface 45 extend across the materials 20, 26 and 40. Such planarized surface may be formed with any suitable processing, including, for example, chemical-mechanical polishing (CMP). A dashed line is provided in FIG. 7A to diagrammatically illustrate an approximate boundary between the illustrated conductive line 42 and the illustrated contact pad 44.

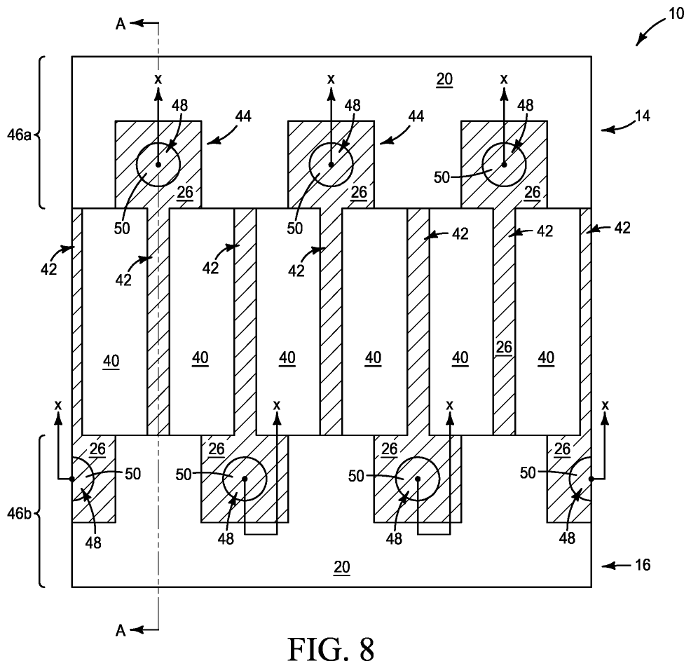

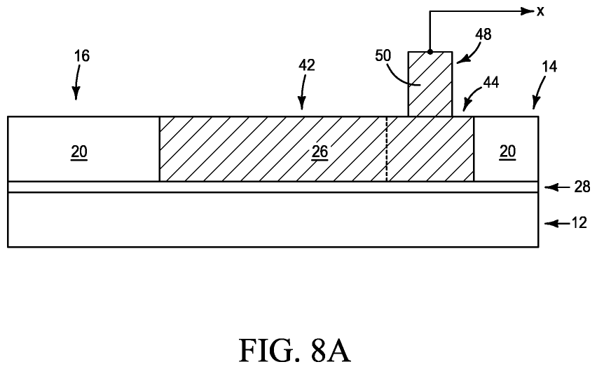

The contact pads 44 may be utilized for establishing electrical connections between the thin conductive lines 42 and other circuitry. Such other circuitry may comprise, for example, one or more of control circuitry (e.g., driver circuitry), sensing circuitry (e.g., sense-amplifier-circuitry), etc. FIG. 8 shows conductive interconnects 48 extending to the contact pads 44, and utilized for electrically coupling such contact pads to circuitry designated as X. The circuitry X may be control circuitry, sensing circuitry, etc.

The interconnects 48 comprise conductive material 50. The conductive material 50 may comprise any suitable electrically conductive composition(s); such as, for example, one or more of various metals (e.g., titanium, tungsten, cobalt, nickel, platinum, ruthenium, etc.), metal-containing compositions (e.g., metal silicide, metal nitride, metal carbide, etc.), and/or conductively-doped semiconductor materials (e.g., conductively-doped silicon, conductively-doped germanium, etc.).

FIG. 8A shows a cross-sectional view along the line A-A of FIG. 8, and shows an example configuration of the interconnect 48.

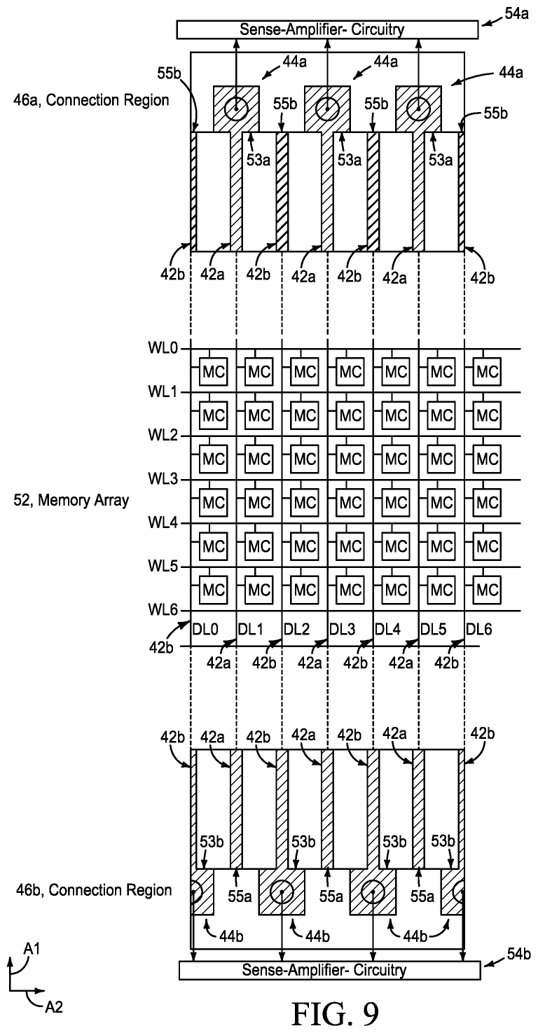

The conductive lines 42 of FIG. 8 may be utilized in highly-integrated applications. In some embodiments, such conductive lines may correspond to wordlines and/or digit lines associated with a memory array. If the conductive lines are wordlines, the contact pads 44 may be utilized to couple the wordlines with appropriate driver circuitry. If the conductive lines are digit lines, the contact pads 44 may be utilized to couple the digit lines with appropriate sensing circuitry (e.g., sense-amplifier-circuitry). FIG. 9 diagrammatically illustrates an example application in which the conductive lines 42 correspond to digit lines (DL0-DL6) associated with a memory array region 52.

In the illustrated embodiment, the connection regions 46a and 46b are laterally offset from one another along the first direction (the A1-axis direction), and the memory array region 52 is between the connection regions 46a and 46b.

The contact pads 44 within the first connection region 46a may be referred to as first contact pads, and the contact pads 44 within the second connection region 46b may be referred to as second contact pads; and in the shown embodiment the first and second contact pads are labeled as 44a and 44b, respectively.

The digit lines extending from the first contact pads 44a may be referred to as first digit lines, and the digit lines extend from the second contact pads 44b may be referred to as second digit lines; and in the shown embodiment the first and second digit lines are labeled as 42a and 42b, respectively.

The digit lines 42a and 42b extend across the memory array region 52. Wordlines (WL0-WL6) also extend across the memory array region. Memory cells (MC) are within the memory array region, with each of the memory cells being uniquely addressed by one of the digit lines in combination with one of the wordlines. The memory cells may comprise any suitable configuration. In some embodiments, the memory cells may be DRAM cells. Each of the memory cells may comprise an access device (e.g., a transistor) in combination with a storage element (e.g., a capacitor). The illustrated region of the memory array may be representative of a small portion of the array. In some embodiments, the memory array may comprise hundreds, thousands, hundreds of thousands, millions, hundreds of millions, etc., of the memory cells; and may comprise an associated suitable number of the digit lines and wordlines.

The contact pads 44a and 44b are utilized for coupling the digit lines 42a and 42b with Sense-Amplifier-Circuitry 54a and 54b.

The embodiment of FIGS. 1-9 shows an application which the contact pads 44a and 44b are polygonally-shaped. The polygonally-shaped contact pads may be, for example, square-shaped, rectangular-shaped, etc. In other embodiments, the contact pads may have other shapes, including, for example, circular shapes, elliptical shapes, etc.

In the shown embodiment of FIG. 9, the contact pads 44a within the first connection region 46a are laterally aligned with one another along the A2-axis direction, and the contact pads 44b within the second connection region 46b are laterally aligned with one another along the A2-axis direction. The contact pads 44a have first outer surfaces 53a from which the first conductive lines 42a project, and the contact pads 44b have second outer surfaces 53b from which the second conductive lines 42b project. The first conductive lines 42a are shown to extend from the first connection region 46a, across the memory array region 52, and into the second connection region 46b, with the ends 55a of the first conductive lines 42a being laterally aligned with the outer surfaces 53b of the contact pads 44b. Similarly, the second conductive lines 42b are shown to extend from the second connection region 46b, across the memory array region 52, and into the first connection region 46a, with the ends 55b of the second conductive lines 42b being laterally aligned with the outer surfaces 53a of the contact pads 44a. In other embodiments, the conductive lines 42a may not extend all the way to the connection region 46b, and/or the conductive lies 42b may not extend all the way to the connection region 46a.

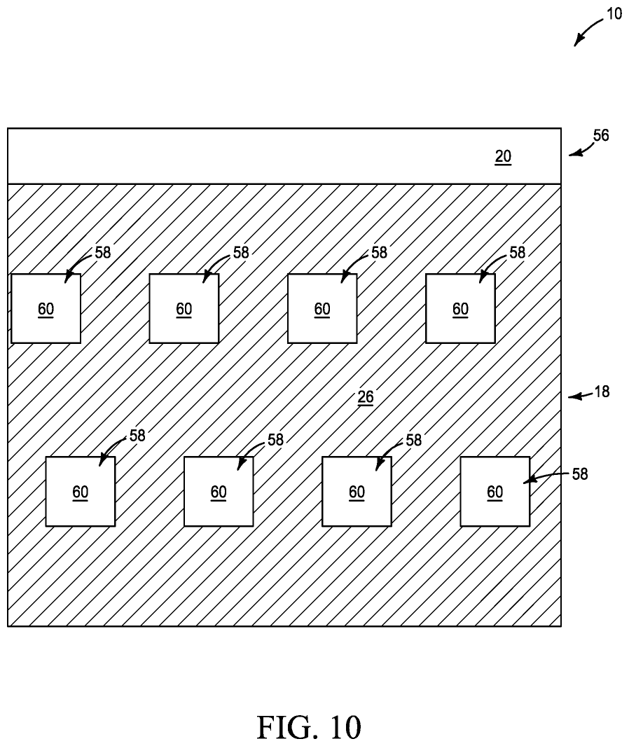

FIGS. 10-17 describe another example method for forming and utilizing conductive lines and contact pads.

FIG. 10 shows the integrated assembly 10 at a process stage alternative to that of FIG. 1. The assembly includes the metal-containing mass 18 comprising the metal-containing material 26. The assembly also includes an insulative structure 56 comprising the insulative material 20. The metal-containing mass is formed adjacent to the insulative structure 56.

Openings 58 are formed to extend through the metal-containing material 26, and such openings are filled with dielectric material 60. The dielectric material 60 may comprise any suitable composition(s); and in some embodiments may comprise one or more of silicon nitride, silicon dioxide, aluminum oxide, etc. The dielectric material 60 may or may not comprise a same composition as the insulative material 20.

In the shown embodiment, the openings 58 are polygonally-shaped. Such openings may be rectangle-shaped, square-shaped, etc. In other embodiments, the openings 58 may have other shapes, including, for example, circular shapes, elliptical shapes, etc.

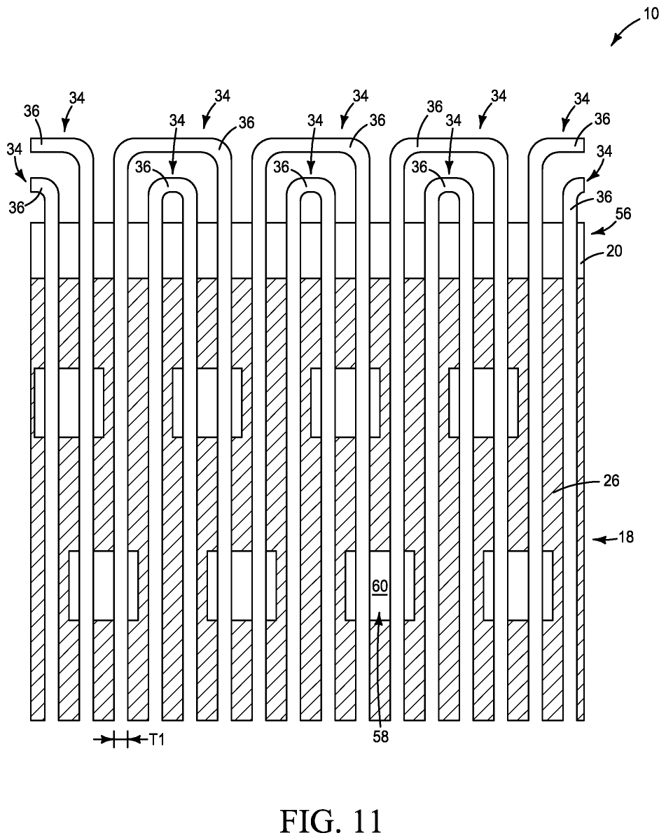

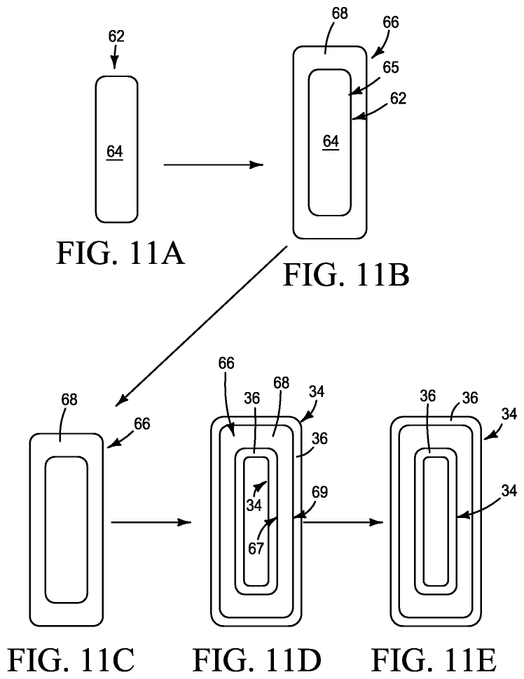

Referring to FIG. 11, spacers 34 are formed. The spacers comprise the spacer material 36 described above with reference to FIG. 3. The spacers 34 may be formed with any suitable processing, and in some embodiments are formed with pitch-multiplication methodologies (e.g., pitch-quadrupling methodology). Example pitch-multiplication methodology is described with reference to FIGS. 11A-11E.

FIG. 11A shows fabrication of a patterned mask 62. The mask 62 may comprise any suitable composition(s) 64, and in some applications may comprise photolithographically-patterned photoresist. The mask 62 is configured as a block.

FIG. 11B shows a first spacer 66 formed along an outer edge 65 of the block corresponding to the mask 62. The spacer 66 comprises spacer material 68. The spacer material 68 is a sacrificial material and may comprise any suitable composition(s), including, for example, one or more of silicon dioxide, silicon nitride, aluminum oxide, etc. The spacer 66 may be considered to be a ring-shaped template structure.

FIG. 11C shows the mask 62 (FIG. 11B) removed to leave the template structure 66.

FIG. 11D shows the spacers 34 formed along inner and outer edges 67 and 69 of the ring-shaped template structure 66.

FIG. 11E shows the template structure 66 (FIG. 11D) removed, to leave the spacers 34.

The spacers 34 of FIG. 11 may have any suitable thickness T1. In some applications, the thickness T1 may be within a range of from about 3 nm to about 15 nm.

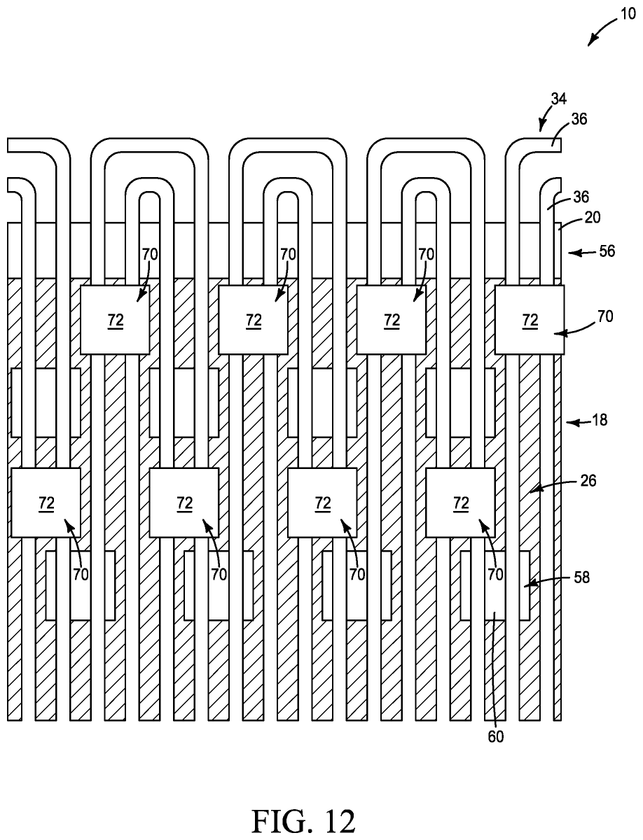

Referring to FIG. 12, contact-pad-defining masking structures 70 are formed over the spacers 34, and over the metal-containing mass 18. The masking structures 70 may comprise any suitable composition(s) 72, and in some embodiments may comprise, consist essentially of, or consist of photoresist. The masking structures 70 are shown to be polygonally-shaped, and in some embodiments may be rectangle-shaped, square-shaped, etc. Alternatively, the masking structures may have other shapes, including, for example, circular shapes, elliptical shapes, etc.

Although the masking structures 70 are shown to be formed over the spacers 36, in other embodiments the processing utilized to form the masking structures may be conducted prior to that utilized to form the spacers so that the masking structures 70 are under the spacers 36.

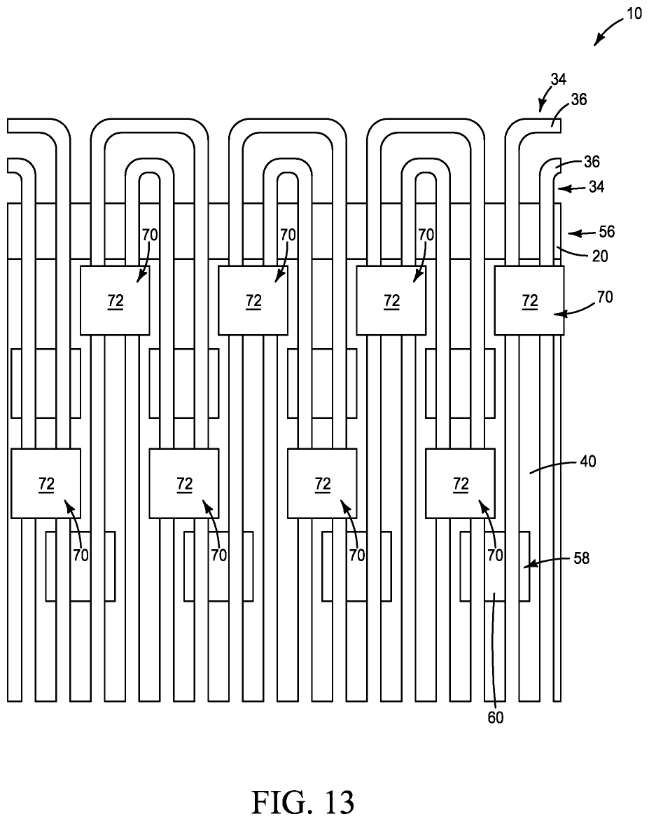

Referring to FIG. 13, the assembly 10 is subjected to processing analogous to that described above with reference to FIG. 6 to replace the exposed metal-containing material 26 (shown in FIG. 12) with the insulative material 40.

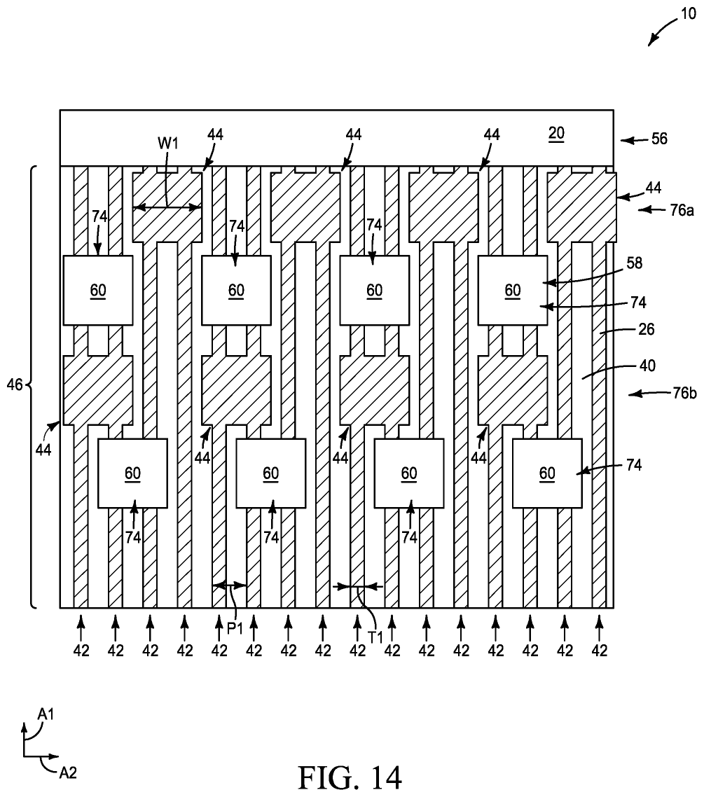

Referring to FIG. 14, the spacers 36 (FIG. 13) and masking structures 70 (FIG. 13) are removed with processing analogous to that described above with reference to FIG. 7. The remaining metal-containing material 26 of the metal-containing mass 18 is patterned into conductive lines 42 and contact pads 44. Some of the conductive lines are broken by the insulative material 60. In some embodiments, such insulative material may be considered to be configured as insulative blocks 74.

In some embodiments, the removal of the exposed metal-containing material described above with reference to FIG. 13 may be considered to be a transfer of the pattern of the spacers 34 (FIG. 13) and the contact-pad-defining masking structures 70 (FIG. 13) into the metal-containing mass 18 to thereby patterned the conductive lines 42 and contact pads 44 of FIG. 14.

The conductive lines 42 have about the thickness T1 of the spacers 34 of FIG. 11. The thickness T1 may be within a range of from about 3 nm to about 15 nm.

The contact pads (landing pads) 44 have widths W1. Such widths may be, for example, within a range of from about 15 nm to about 50 nm.

The conductive lines 42 are formed to be on a pitch P1. Such pitch may be, for example, within a range of from about 6 nm to about 50 nm. Accordingly, the thin conductive lines 42 may be incorporated into highly-integrated architectures.

The conductive lines 42 and contact pads 44 are patterned from the same conductive material 26, and accordingly comprise a same composition as one another. In some embodiments, such composition may comprise, consist essentially of, or consist of ruthenium.

The contact pads 44 may be considered to be within a connection region 46, and the conductive lines 42 may be considered to extend from such connection region. In the illustrated embodiment, the conductive lines extend along the first direction corresponding to the A1-axis direction.

The contact pads 44 within the connection region 46 are arranged in two sets 76a and 76b, which may be referred to as a first set and a second set, respectively. The sets 76a and 76b are offset relative to one another along the A1-axis direction. The contact pads 44 within the first set 76a are aligned with one another along the A2-axis direction, and the contact pads 44 within the second set 76b are also aligned with one another along the A2-axis direction.

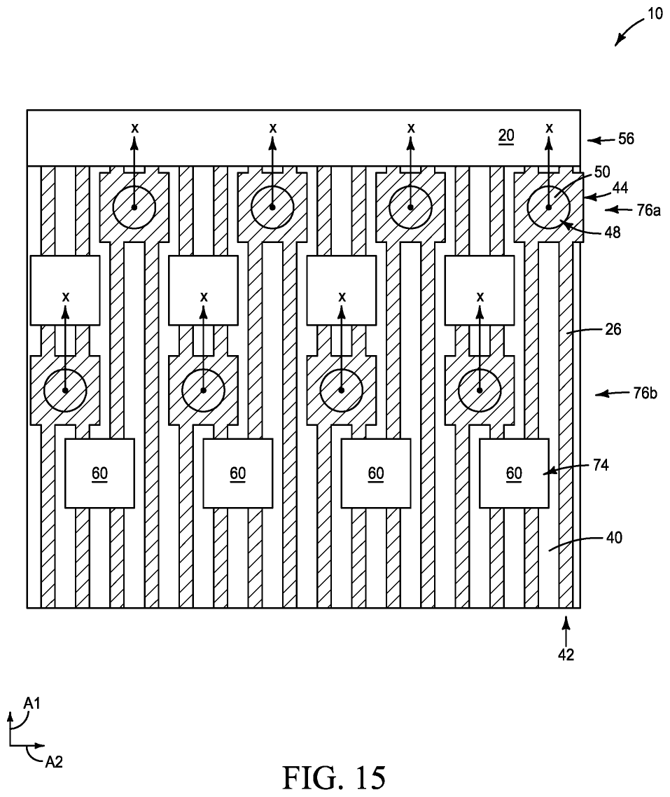

The contact pads 44 may be utilized for establishing electrical connections between the thin conductive lines 42 and other circuitry, similar to the embodiment described above with reference to FIG. 8. FIG. 15 shows the conductive interconnects 48 extending to the contact pads 44, and utilized for electrically coupling such contact pads to circuitry designated as X. The circuitry X may be control circuitry, sensing circuitry, etc. The interconnects 48 comprise the conductive material 50.

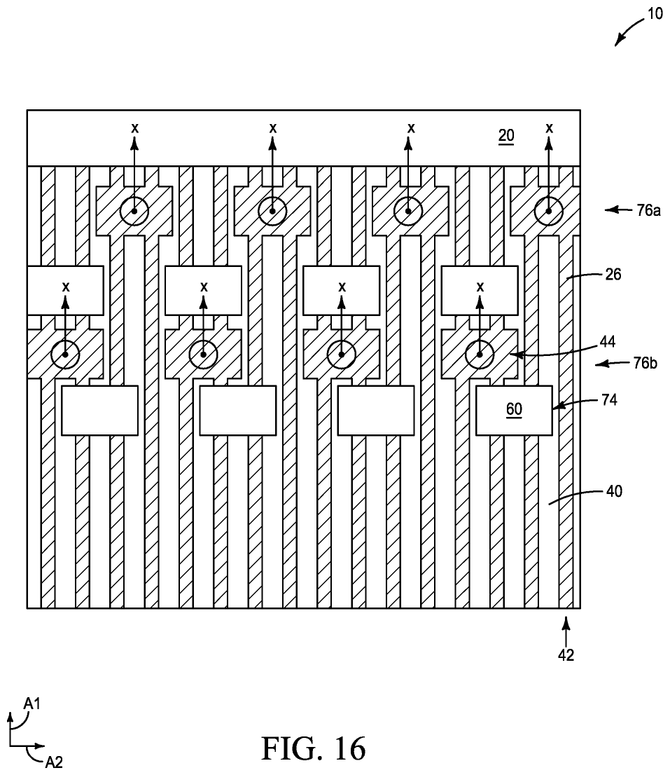

The square-shaped contact pads 44 and square-shaped insulative blocks 74 may be utilized in some applications. In other applications, it may be advantageous to modify shapes of contact pads 44, and/or to modify shapes of the insulative blocks 74, to achieve tighter packing. For instance, FIG. 16 shows an example embodiment in which the contact pads 44 and insulative blocks 74 are configured as rectangles which are thinner along the A1-axis direction than along the A2-axis direction.

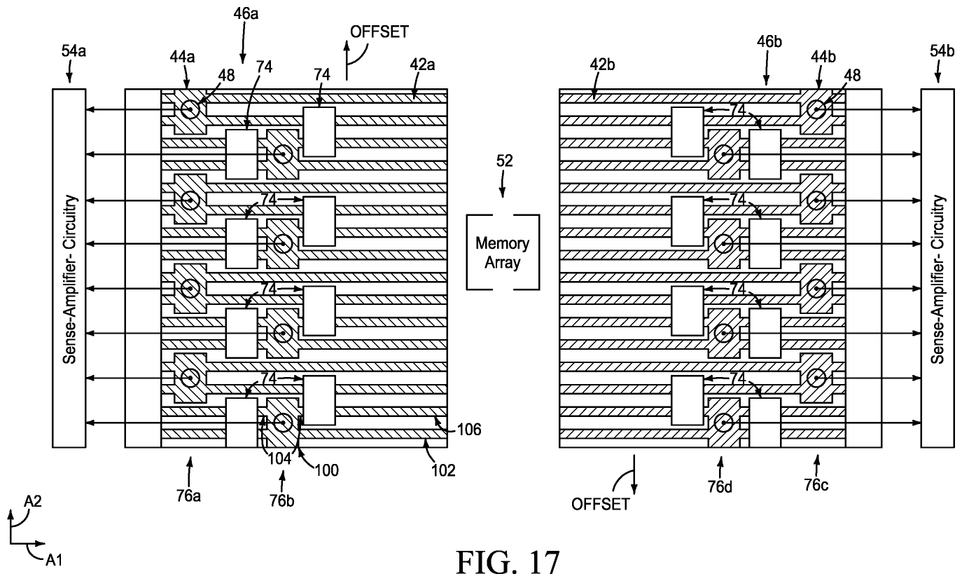

The conductive lines 42 of FIGS. 15 and 16 may be utilized in highly-integrated applications. In some embodiments, such conductive lines may correspond to wordlines and/or digit lines associated with a memory array, analogous to the embodiment described above with reference to FIG. 9. FIG. 17 diagrammatically illustrates an example application analogous to that described above with reference to FIG. 9. The memory array 52 may be identical to that described above with reference to FIG. 9. The structures 44, 42, 74, etc., are incorporated into first and second connection regions 46a and 46b, which are shown to be mirror images of one another across the memory array 52. In practice, the illustrated region 46b should be laterally offset relative to the illustrated region 46a along the A2 axis (as shown by arrows label “OFFSET”) so that digit lines coupled with the connection region 46b alternate with digit lines coupled with the connection region 46a across the array 52, similar to the embodiment shown in FIG. 9.

The contact pads 44 within the first connection region 46a are first contact pads 44a, and the contact pads within the second connection region 46b are second contact pads 44b. First digit lines 42a extend from the first contact pads 44a, and second digit lines 42b extend from the second contact pads 44b. The contact pads 44a may be considered to be arranged within the first and second sets 76a and 76b described above with reference to FIG. 14, and the contact pads 44b may be considered to be arranged within third and fourth sets 76c and 76d.

The contact pads 44a and 44b are shown to be utilized for coupling the digit lines 42a and 42b with Sense-Amplifier-Circuitry 54a and 54b.

The illustrated embodiment of FIG. 17 has each of the contact pads 44 coupled with an associated one of the conductive lines 42. For instance, one of the contact pads within the set 76b is labeled 100, and is coupled with an associated conductive line labeled 102. Each of the contact pads is also coupled with a conductive segment which is not part of the associated conductive line. For instance, the contact pad 100 is coupled with a conductive segment labeled 104. The conductive segment 104 is aligned with another conductive line which is not the associated conductive line, and in the shown embodiment is aligned with a conductive line labeled 106. The conductive segment 104 is electrically isolated from the conductive line 106 by an insulative block 74.

The processing described herein may advantageously enable metal-containing material (e.g., ruthenium-containing material) to be cost-effectively patterned into highly integrated structures (e.g., highly integrated wordlines, digit lines, etc.).

The assemblies and structures discussed above may be utilized within integrated circuits (with the term “integrated circuit” meaning an electronic circuit supported by a semiconductor substrate); and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

Unless specified otherwise, the various materials, substances, compositions, etc. described herein may be formed with any suitable methodologies, either now known or yet to be developed, including, for example, atomic layer deposition (ALD), chemical vapor deposition (CVD), physical vapor deposition (PVD), etc.

The terms “dielectric” and “insulative” may be utilized to describe materials having insulative electrical properties. The terms are considered synonymous in this disclosure. The utilization of the term “dielectric” in some instances, and the term “insulative” (or “electrically insulative”) in other instances, may be to provide language variation within this disclosure to simplify antecedent basis within the claims that follow, and is not utilized to indicate any significant chemical or electrical differences.

The terms “electrically connected” and “electrically coupled” may both be utilized in this disclosure. The terms are considered synonymous. The utilization of one term in some instances and the other in other instances may be to provide language variation within this disclosure to simplify antecedent basis within the claims that follow.

The particular orientation of the various embodiments in the drawings is for illustrative purposes only, and the embodiments may be rotated relative to the shown orientations in some applications. The descriptions provided herein, and the claims that follow, pertain to any structures that have the described relationships between various features, regardless of whether the structures are in the particular orientation of the drawings, or are rotated relative to such orientation.

The cross-sectional views of the accompanying illustrations only show features within the planes of the cross-sections, and do not show materials behind the planes of the cross-sections, unless indicated otherwise, in order to simplify the drawings.

When a structure is referred to above as being “on”, “adjacent” or “against” another structure, it can be directly on the other structure or intervening structures may also be present. In contrast, when a structure is referred to as being “directly on”, “directly adjacent” or “directly against” another structure, there are no intervening structures present. The terms “directly under”, “directly over”, etc., do not indicate direct physical contact (unless expressly stated otherwise), but instead indicate upright alignment.

Structures (e.g., layers, materials, etc.) may be referred to as “extending vertically” to indicate that the structures generally extend upwardly from an underlying base (e.g., substrate). The vertically-extending structures may extend substantially orthogonally relative to an upper surface of the base, or not.

Some embodiments include an integrated assembly having a first connection region with first contact pads. A second connection region is offset from the first connection region along a first direction. Second contact pads are within the second connection region. The first contact pads are aligned with one another along a second direction substantially orthogonal to the first direction. The second contact pads are aligned with one another along the second direction. A memory array region is between the first and second connection regions. First conductive lines extend from the first contact pads of the first connection region and across the memory array region. Second conductive lines extend from the second contact pads of the second connection region and across the memory array region. The first conductive lines, second conductive lines, first contact pads and second contact pads have an identical conductive composition as one another.

Some embodiments include an integrated assembly comprising a first connection region having first contact pads. A second connection region is offset from the first connection region along a first direction and comprises second contact pads. The first contact pads are arranged in a first set and a second set, with the first contacts pads of the first set being aligned with one another along a second direction substantially orthogonal to the first direction, with the first contact pads of the second set being aligned with one another along the second direction, and with the first contact pads of the first set being offset from the first contact pads of the second set along the first direction. The second contact pads are arranged in a third set and a fourth set, with the second contacts pads of the third set being aligned with one another along the second direction, with the second contact pads of the fourth set being aligned with one another along the second direction, and with the second contact pads of the third set being offset from the second contact pads of the fourth set along the first direction. A memory array region is between the first and second connection regions. First conductive lines extend from the first contact pads of the first connection region and across the memory array region. Second conductive lines extend from the second contact pads of the second connection region and across the memory array region. The first conductive lines, second conductive lines, first contact pads and second contact pads have an identical conductive composition as one another.

Some embodiments include a method of forming an integrated assembly. A metal-containing mass is formed adjacent to an insulative structure. Template structures are formed over the metal-containing mass. Spacers are formed along outer edges the template structures, and then the template structures are removed. One or more contact-pad-defining masking structures are formed over the metal-containing mass. Patterns of the spacers and the one or more contact-pad-defining masking structures are transferred into the metal-containing mass to form conductive lines and contact pads from the metal-containing mass. The contact pads are within a connection region, and the conductive lines extend from the connection region to a memory array region.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

I/We claim:

1. An integrated assembly, comprising:
a first connection region comprising first contact pads;
a second connection region offset from the first connection region along a first direction and comprising second contact pads; the first contact pads being aligned with one another along a second direction substantially orthogonal to the first direction, and the second contact pads being aligned with one another along the second direction;
a memory array region between the first and second connection regions;
first conductive lines extending from the first contact pads of the first connection region and across the memory array region;
second conductive lines extending from the second contact pads of the second connection region and across the memory array region; and
the first conductive lines, second conductive lines, first contact pads and second contact pads comprising an identical conductive composition as one another.

2. The integrated assembly of claim 1 wherein said identical composition comprises one or more metals.

3. The integrated assembly of claim 1 wherein said identical composition comprises ruthenium.

4. The integrated assembly of claim 1 wherein said identical composition consists of ruthenium.

5. The integrated assembly of claim 1 wherein:
the first contact pads have first outer surfaces from which the first conductive lines project;
the second contact pads have second outer surfaces from which the second conductive lines project;
the first conductive lines extend to the second connection region and have first terminal ends laterally aligned with said second outer surfaces; and
the second conductive lines extend to the first connection region and have second terminal ends laterally aligned with said first outer surfaces.

6. The integrated assembly of claim 5 wherein the first and second contact pads are polygonally-shaped, and wherein the first and second outer surfaces a flat surfaces.

7. The integrated assembly of claim 6 wherein the polygonally-shaped first and second contact pads are rectangular-shaped.

8. The integrated assembly of claim 6 wherein the polygonally-shaped first and second contact pads are square-shaped.

9. The integrated assembly of claim 1 wherein the first and second conductive lines are digit lines.

10. The integrated assembly of claim 9 wherein the first and second contact pads are electrically coupled with sense-amplifier-circuitry.

11. An integrated assembly, comprising:
a first connection region comprising first contact pads;
a second connection region offset from the first connection region along a first direction and comprising second contact pads; the first contact pads being arranged in a first set and a second set, with the first contacts pads of the first set being aligned with one another along a second direction substantially orthogonal to the first direction, with the first contact pads of the second set being aligned with one another along the second direction, and with the first contact pads of the first set being offset from the first contact pads of the second set along the first direction; the second contact pads being arranged in a third set and a fourth set, with the second contacts pads of the third set being aligned with one another along the second direction, with the second contact pads of the fourth set being aligned with one another along the second direction, and with the second contact pads of the third set being offset from the second contact pads of the fourth set along the first direction;
a memory array region between the first and second connection regions;
first conductive lines extending from the first contact pads of the first connection region and across the memory array region;
second conductive lines extending from the second contact pads of the second connection region and across the memory array region; and
the first conductive lines, second conductive lines, first contact pads and second contact pads comprising an identical conductive composition as one another.

12. The integrated assembly of claim 11 wherein the memory array is a DRAM array.

13. The integrated assembly of claim 11 wherein said identical composition comprises one or more metals.

14. The integrated assembly of claim 11 wherein said identical composition comprises ruthenium.

15. The integrated assembly of claim 11 wherein said identical composition consists of ruthenium.

16. The integrated assembly of claim 11 wherein:
each of the first and second contact pads is electrically coupled with an associated one of the first and second conductive lines and with a conductive segment which is not part of the associated one of the first and second conductive lines;
the conductive segment is aligned with another of the first and second conductive lines besides said associated one of the first and second conductive lines;
an insulative block is between the conductive segment and said other of the first and second conductive lines; and
the insulative block electrically isolates the conductive segment from the other of the first and second conductive lines.

17. The integrated assembly of claim 11 wherein the first and second contact pads are rectangular-shaped.

18. The integrated assembly of claim 11 wherein the first and second contact pads are square-shaped.

19. The integrated assembly of claim 11 wherein the first and second conductive lines are digit lines.

20. The integrated assembly of claim 19 wherein the first and second contact pads are electrically coupled with sense-amplifier-circuitry.

21. A method of forming an integrated assembly, comprising:
forming a metal-containing mass adjacent an insulative structure;
forming template structures over the metal-containing mass;
forming spacers along outer edges the template structures, and then removing the template structures;
forming one or more contact-pad-defining masking structures over the metal-containing mass; and
transferring patterns of the spacers and the one or more contact-pad-defining masking structures into the metal-containing mass to form conductive lines and contact pads from the metal-containing mass; the contact pads being within a connection region, and the conductive lines extending from the connection region to a memory array region.

22. The method of claim 21 wherein the template structures are blocks.

23. The method of claim 22 wherein said blocks comprise photoresist.

24. The method of claim 21 wherein the template structures are rings, and wherein the spacers are formed along the outer edges of the rings as well as along inner edges of the rings.

25. The method of claim 24 wherein said rings comprise one or more of silicon dioxide, silicon nitride and aluminum oxide.

26. The method of claim 21 wherein the metal-containing mass comprises ruthenium.

27. The method of claim 21 wherein the metal-containing mass consists essentially of ruthenium.

28. The method of claim 21 wherein the metal-containing mass consists of ruthenium.

29. The method of claim 21 wherein the one or more contact-pad-defining masking structures are formed over regions of the spacers.

30. The method of claim 29 wherein the one or more contact-pad-defining masking structures comprise photoresist.

31. The method of claim 21 wherein the insulative structure comprises projections, with bay regions being defined between the projections; wherein the metal-containing mass extends into the bay regions; and wherein the one or more contact-pad-defining masking structures includes a single one of the contact-pad-defining masking structures which extends across two or more of the bay regions.

32. The method of claim 21 wherein openings are formed to extend through the metal-containing mass prior to forming the spacers; and wherein at least some of the conductive lines are broken by the openings.
